(19) United States
(12) Patent Application Publication
(10) Pub. No.: US 2009/0290725 A1
(43) Pub. Date: Nov. 26, 2009

(54) AUTOMATIC EQUALIZER ADJUSTMENT SETTING FOR PLAYBACK OF MEDIA ASSETS

(75) Inventor: Szu Wen Huang, Fremont, CA (US)

Correspondence Address: TOWNSEND AND TOWNSEND AND CREW, LLP, TWO EMBARCADERO CENTER, 8TH FLOOR, SAN FRANCISCO, CA, 94111-3834, US

(73) Assignee: Apple Inc., Cupertino, CA (US)

(21) Appl. No.: 12/188,046

(22) Filed: Aug. 7, 2008

Related U.S. Application Data
(60) Provisional application No. 61/055,233, filed on May 22, 2008.

(51) Int. Cl. H03G 5/16

(52) U.S. Cl. 381/103

(57) ABSTRACT

Systems and methods are disclosed in which correspondences with content or other media assets can be established such that a media player or portable media device can automatically modify or adjust an equalizer setting based on information associated with the content or other media assets. The media player may automatically adjust one or more equalizer settings based on genre, artist, album, or the like. In some embodiments, metadata associated with content or other media assets can be analyzed to determine normalized data thereby potentially grouping content into supersets. Based on the normalized data, the media player may automatically adjust equalizer settings for each superset or grouping of content. Correspondences with one or more accessories may be established such that the media player can automatically modify or adjust an equalizer setting based on the one or more accessories.

### CROSS-REFERENCES TO RELATED APPLICATIONS

This application claims benefit of U.S. Provisional Application No. 61/055,233, filed May 22, 2008, which application is incorporated herein by reference for all purposes.

### BACKGROUND OF THE INVENTION

Electronic devices, such as portable media players, cellular phones, personal digital assists (PDAs), and the like, are prevalent in today's marketplace, as are the peripheral electronic devices that support their use, such as docking stations and the like. As competition in the personal electronics marketplace becomes ever more heated, consumers have become more demanding in terms of both the functionality and use of such devices.

Users listen to, watch, or otherwise receive and consume content in a variety of contexts. For example, it is common to listen to music while driving, riding public transit, exercising, hiking, doing chores, or the like. Additionally, users now are more often using media players to receive radio, television, and satellite broadcasts, Global Positioning and other broadcast-based location services for navigation and recreation in addition to the playback of content stored on the media players.

Graphic equalizers can be common in middle- and high-end stereophonic sound systems for consumer use, and may also be available for use in fine-tuning sound in media players. Media players or portable media device may allow users to determine settings for audio and video signals by controlling the graphic equalizer. For example, the equalizer may control timbre or other attributes associated with the signals. In a conventional equalizer, controls are provided in accordance with a plurality of frequency band units, and the user manually manipulates controls for one or more of the frequency band units so that the desired setting may be achieved. However, a user unfamiliar with the manipulation of the equalizer may listen to all music with one setting, or the quality of the music may be reduced due to unskilled equalizing manipulation.

Accordingly, what is desired are improved methods and apparatus for solving the problems discussed above. Additionally, what is desired are improved methods and apparatus for reducing some of the drawbacks discussed above.

### BRIEF SUMMARY OF THE INVENTION

In various embodiments, correspondences with content or other media assets can be established such that a media player or portable media device can automatically modify or adjust an equalizer setting based on information associated with the content or other media assets. For example, when a U2 song begins to play, the media player may adjust the equalizer setting to the rock-and-roll equalizer setting. In another example, when a Miles Davis song begins to play, the media player may adjust one or more equalizer settings to a jazz setting.

In some embodiments, metadata associated with content or other media assets can be analyzed to determine normalized data. The normalized data can represented a more common or general set of information, such as grouping several sub-genres into a superset called a macro-genre. The normalized data or groupings can be associated with equalizer settings. The media player may automatically adjust the equalizer settings based on the normalized data.

In further embodiments, correspondences with one or more accessories can be established such that the media player can automatically modify or adjust an equalizer setting based on the one or more accessories. Settings may be changed in response to whether earplugs are attached to the media player, or whether the media player is attached to a docking system.

A further understanding of the nature and the advantages of the inventions disclosed herein may be realized by reference to the remaining portions of the specification and the accompanying drawings.

### BRIEF DESCRIPTION OF THE DRAWINGS

In order to better illustrate and describe examples and/or embodiments of those inventions found within the specification, reference may be made to the accompanying drawings. The additional details used to describe the accompanying drawings should not be considered as limitations to the scope of any of the disclosed inventions, the presently described examples and/or embodiments of the inventions, and/or the presently understood best mode of the inventions.

FIG. 1 is a block diagram of a media player that may incorporate embodiments of the present invention;

FIGS. 2A and 2B is an illustration of a graphical equalizer that may be implemented using a media player in one embodiment according to the present invention;

FIG. 3 is a flowchart of a method for automatic equalizer adjustment setting for playback of content in one embodiment according to the present invention;

FIG. 4 is a flowchart of a method for generating a mapping between information related to content and equalizer settings in one embodiment according to the present invention;

FIGS. 5, 6, and 7 illustrate examples of mappings that may be implemented in various embodiments according to the present invention;

FIG. 8 is a flowchart of a method for modifying equalizer settings based on content in one embodiment according to the present invention;

FIG. 9 is a flowchart of a method for modifying equalizer settings based on an accessory attached to a media player in one embodiment according to the present invention;

FIG. 10 is a flowchart of a method for uploading equalizer setting mappings to a media player in one embodiment according to the present invention; and

FIG. 11 is a simplified block diagram of a computer system that may incorporate embodiments of the present invention.

### DETAILED DESCRIPTION OF THE INVENTION

In various embodiments, a user can interact with a media player or portable media device to browse or otherwise initiate playback of content or other media assets. The media player or portable media device may analyze information associated with content or other media assets to determine adjustments to equalizer settings for playback of the content. The media player may selectively switch between pre-defined or user-configured equalizer settings based on metadata, such as genre, artist, album, or the like. The media player may output content for playback to the user using an automatically determined equalizer setting.

Aspects of the environments within which various examples and/or embodiments of those invention found within the specification operate will first be described.

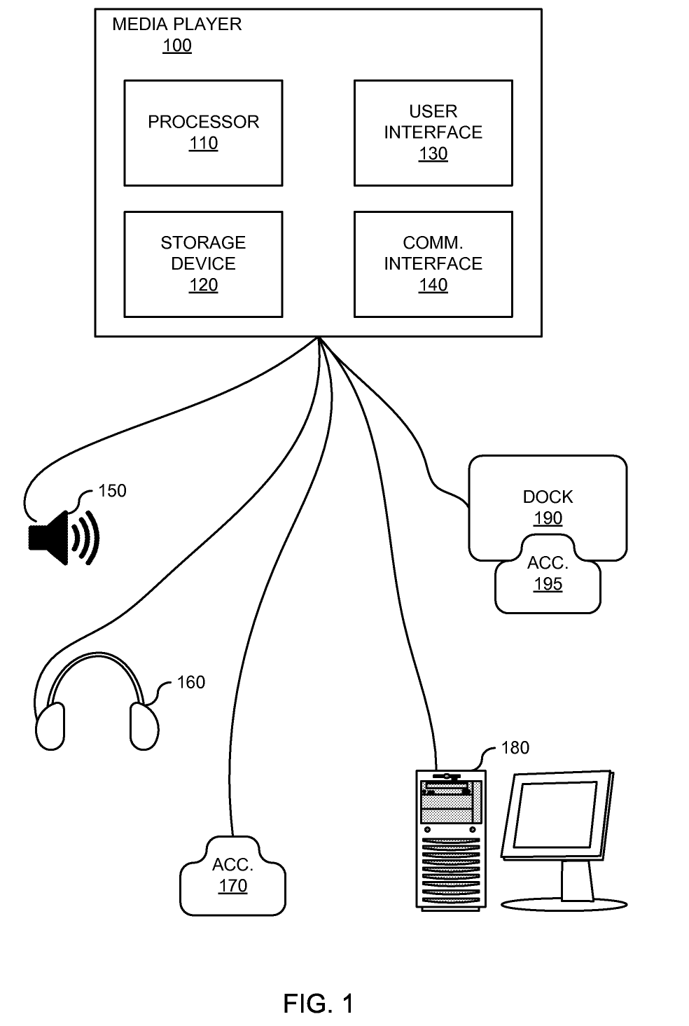

FIG. 1 is a block diagram of media player 100 that may incorporate embodiments of the present invention. In general, a media player stores content and/or media assets, such as audio tracks, movies, or photos that can be played or displayed on the media player. One example of media player 100 can be the iPod® media player, which is available from Apple, Inc. of Cupertino, Calif. Another example of media player 100 can be a personal computer, such as a laptop or desktop.

In this example, media player 100 includes processor 110, storage device 120, user interface 130, and communications interface 140. Processor 110 can control various functionalities associated with media player 100. Media play 100 may output audio content, video content, image content, and the like. Media player 100 may also output metadata or other information associated with content, such as track information and album art.

Typically, a user may load or store content onto media player 100 using storage device 120. Storage device 120 can include read-only memory (ROM), random access memory (RAM), non-volatile memory, flash memory, floppy disk, hard disk, or the like. A user may interact with user interface 130 of media player 100 to view or consume content. Some examples of user interface 130 can include buttons, click wheels, touch pads, displays, touch screens, and other input/output devices.

Media player 100 can include one or more connectors or ports that can be used to load content, retrieve content, interact with applications running on media player 100, interface with external devices, and the like. In this example, media player 100 includes communications interface 140. Some examples of communications interface 140 can include universal serial bus (USB) interfaces, IEEE 1394 (or FireWire/iLink®) interfaces, universal asynchronous receiver/transmitters (UARTs), wired and wireless network interfaces, transceivers, and the like. Media player 100 may connect to devices, accessories, private and public communications networks (e.g., the Internet), or the like, using communications interface 140.

In one example, media player 100 can be coupled via a wired and/or wireless connector or port to output audio and/or other information to speakers 150. In another example, media player 100 may be coupled via a wired and/or wireless connector or port to output audio and/or other information to headphones 160. In yet another example, media player 100 may be coupled via a wired and/or wireless connector or port to interface with an accessory 170 or a host computer 180. The same connector or port may enable different connections at different times.

Media player 100 can be physically inserted into docking system 190. Media player 100 may be coupled via a wired and/or wireless connector or port to interface with docking system 190. Docking system 190 may also enable one or more accessory devices 195 to couple with wires or wirelessly to interface with media player 100. Many different types and functionalities of accessory devices 170 and 195 can interconnect to or with media player 100. For example, an accessory may allow a remote control to wirelessly control media player 100. As another example, an automobile may include a connector into which media player 100 may be inserted such that an automobile media system can interact with media player 100, thereby allowing media content stored on media player 100 to be played within the automobile.

In various embodiments, media player 100 can receive content or other media assets from a computer system (e.g., host computer 160). The computer system may serve to enable a user to manage media assets stored on the computer system and/or stored on media player 100. As an example, communications interface 140 may allow media player 100 to interface with host computer 160. Host computer 160 may execute a media management application to manage media assets, such as loading songs, movies, photos, or the like, onto media player 100. The media management application may also create playlists, record or rip content, schedule content for playback or recording, or the like. One example of a media management application can be iTunes®, produced by Apple, Inc. of Cupertino, Calif.

In some embodiments, media player 100 may include hardware and/or software elements configured to control frequency bands for the playback of content or other media assets. In various embodiments, media player 100 may include a graphic equalizer embodied as a high-fidelity audio control that allows a user to see graphically and control individually a number of different frequency bands. The graphic equalizer may include several audio filter/amplifiers, each centered at a specific frequency in an audio range. The graphic equalizer may allow a user to determine an equalizer setting, such as timbre, by controlling one or more of the frequency bands. Media player 100 can provide an equalizer with controls associated with a plurality of frequency band units. The user may manipulate a control panel of the equalizer so that the desired equalizer settings can be adjusted.

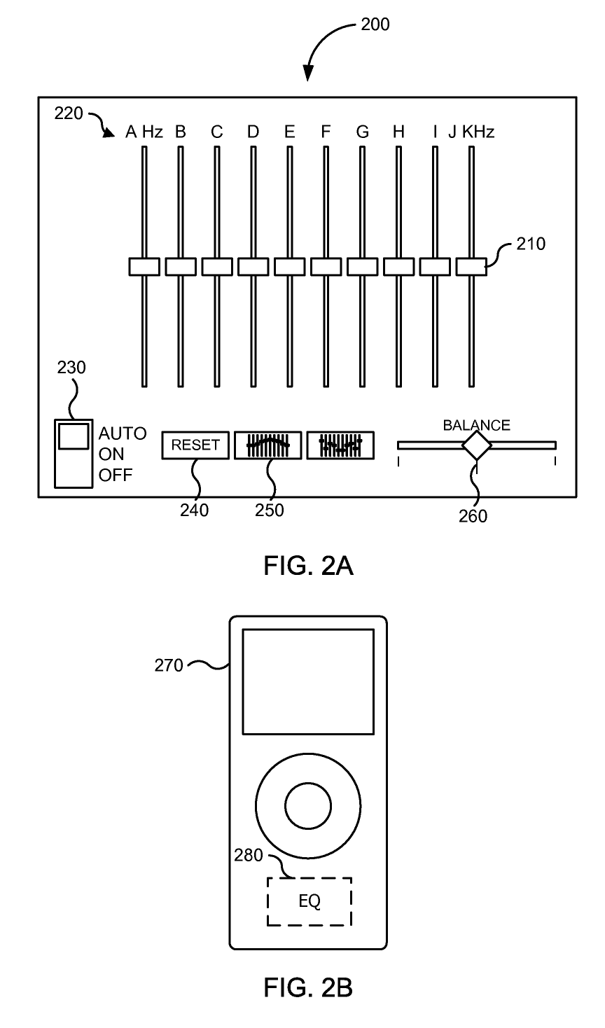

FIG. 2A is an illustration of graphic equalizer 200 that may be implemented using media player 270 in one embodiment according to the present invention. Media player 270 may be embodied as media player 100 of FIG. 1. In this example, graphic equalizer 200 can include a set of gain controls 210 for adjusting a set of frequency bands 220 (e.g., bands A, B, C, D, E, F, G, H, I, and J).

In various embodiments, gain (or volume) controls 210 are represented (e.g., physically as an accessory attached to media player 100 or as displayed using a graphical user interface) as slide potentiometers that may be adjusted by moving a control button up or down. Gain within a given frequency band or channel may be increased by sliding the control button associated with the given frequency band upwards. In some examples, the slide potentiometers for each frequency band or channel may be placed side-by-side, with the lowest-frequency unit (e.g., band A) at the left and the highest-frequency unit at the right (e.g., band J). In these examples, the positions of the buttons may appear to follow a graphical curve that represents the gain as a function of frequency for each channel.

In various embodiment, graphic equalizer 200 can include additional settings. For example, graphical equalizer 200 can include control 230 that is configured to disable functionality of graphical equalizer 200, enable functionality of graphical equalizer 200, or enable automatic functionality of graphical equalizer 200. The automatic functionality of graphical equalizer 200 will be explained in further detail below.

Graphical equalizer 200 may further include control 240 configured to reset each of the channels to a predetermined default level. Graphical equalizer 200 may further include one or more controls, such as control 250 that is configure to set each of the channels to predetermined level. The predetermined levels associated with control 250 may be hard-coded or user configurable. Graphical equalizer 200 may further include control 260 for adjusting the balance of signals, such as the Left-Right balance of an audio signal. While graphical equalizer 200 may be described in the context of audio signals, other types of controls may be included to correspond to any number of audio-visual settings, such as brightness, contrast, hue, saturation, gamma, or the like.

In one example of operation, a signal (e.g., a digital audio signal) may be generated from content stored or otherwise accessible to media player 270. The audio data can be supplied to digital equalizer 280 associated with graphical equalizer 200. Digital equalizer 280 may include a hardware equalizer module of media player 270. The functions of digital equalizer 280 may further be performed by a processor of media player 270 (e.g., processor 110 associated with media player 100).

In various embodiments, digital equalizer 280 divides the audio frequency bands into N bands. Information representing the settings provided by gain controls 210 allow equalization control to be performed according to the corresponding frequency band. In various embodiments, users can adjust settings, such as timbres by audio frequency band by manipulating gain controls 210.

Digital equalizer 280, to which the audio data is supplied, equalizes the audio data over the frequency bands according to the settings associated with graphic equalizer 200, and outputs the result. For example, the results may be output to digital-to-analog converter for playback to the user using one or more of headphones, speakers, stereo systems, or the like.

In some embodiments, a user frequently manipulates settings associated with graphic equalizer 200 according to the type or category of music or other content so as to determine the timbre. A user unfamiliar with the manipulation of equalizer settings may listen to all music or output content with one setting. The user may also reduce the quality of the music or the output of other content due to unskilled equalizing manipulation. According to various embodiments, equalizer settings may be automatically adjusted. Therefore, the user may experience a more pleasant audio-visual presentation of content.

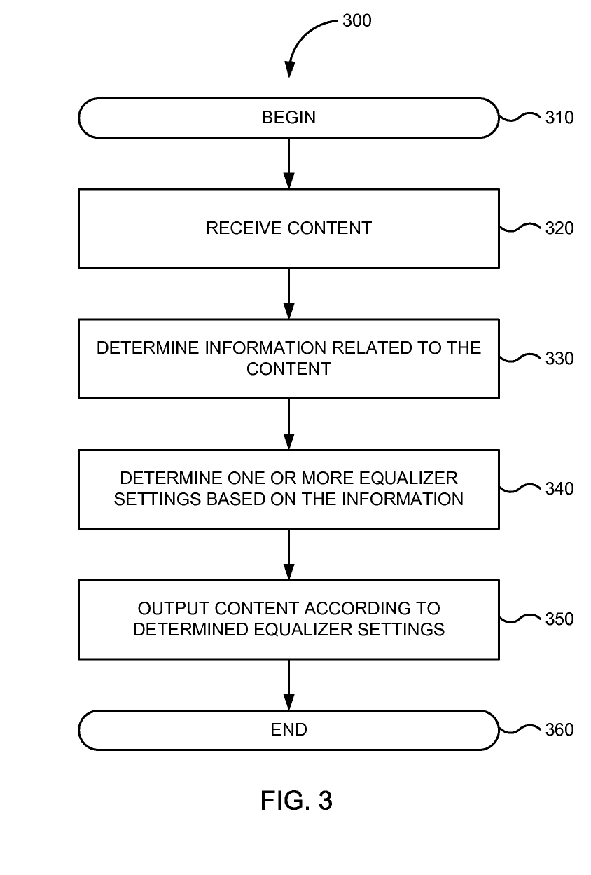

FIG. 3 is a flowchart of method 300 for automatic equalizer adjustment setting for playback of content in one embodiment according to the present invention. The processing depicted in FIG. 3 may be performed by software modules (e.g., instructions or code) executed by a processor of a computer system, by hardware modules of the computer system, or combinations thereof. FIG. 3 begins in step 310.

In step 320, content is received. Content may include music, audiobooks, images, photos, movies, and the like. The content may be stored on a device, such as media player 100, or may be communicated to the device using any combination of analog or digital forms. The content may include or otherwise be associated with metadata. The metadata may describe ownership information, a title, artist, album, genre, category, type, bit-rate, encoding, format, container, or the like.

In step 330, information related to the content is determined. In various embodiments, media player 100 may extract the metadata, such as MP3 ID tags from the content. Media player 100 may further communicated with a content management application or other information service to determine information related to the content.

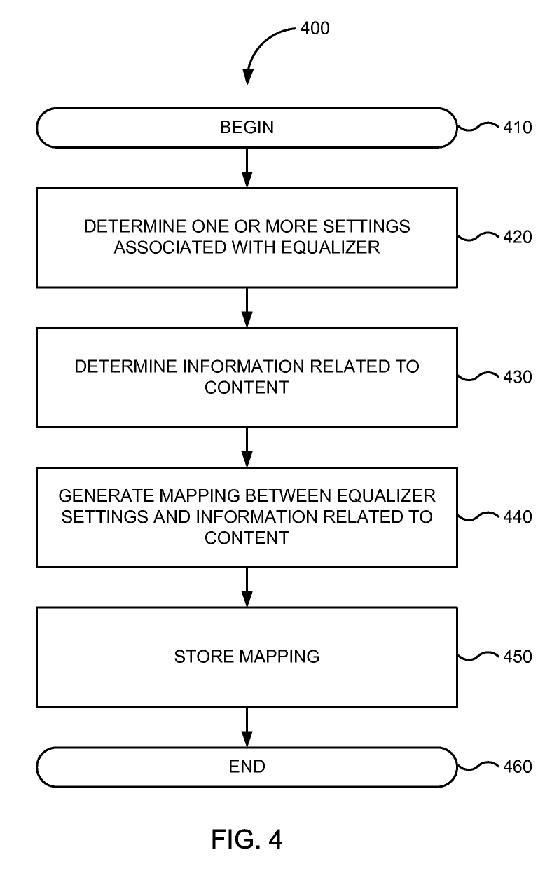

In step 340, one or more equalizer settings are determined based on the information related to the content. For example, information may be determined indicative of the levels associated with each gain control 210 associated with graphic equalizer 200. In various embodiments, the one or more equalizer settings are determined based on a mapping between the information related to the content and the equalizer settings. One example of this is explained further with respect to FIG. 4.

In step 350, content is output according to the determined equalizer settings. For example, digital equalizer 280 may equalize a signal associated with the content over the frequency bands according to the determined settings. FIG. 3 ends in step 360.

In various embodiments, equalizer settings may be automatically adjusted based on the content. For example, different equalizer settings may be selected based on the artist, genre, or the like associated with content. In further embodiments, equalizer settings may be automatically adjusted based on whether an accessory is present and/or the type of accessory. Accordingly, a user may be provided an higher quality audio-visual experience without having to manually manipulate settings for each different type of content.

FIG. 4 is a flowchart of method 400 for generating a mapping between information related to content and equalizer settings in one embodiment according to the present invention. FIG. 4 begins in step 410.

In step 420, one or more settings associated with an equalizer are determined. The one or more settings can include, for example, channel levels, low range levels, midrange levels, high range levels, predetermined values, frequency schemes, or the like.

In step 430, information related to content is determined. In step 440, a mapping is generated between the equalizer settings and information related to the content. The mapping may include information defining or otherwise specifying a relationship between one or more of equalizer settings and a portion of the information related to the content. One example of the mappings may be lookup lists between one or more settings and information related to the content.

In step 450, the mapping is stored. For example, the mapping may be stored on media player 100 for subsequent use. FIG. 4 ends in step 460.

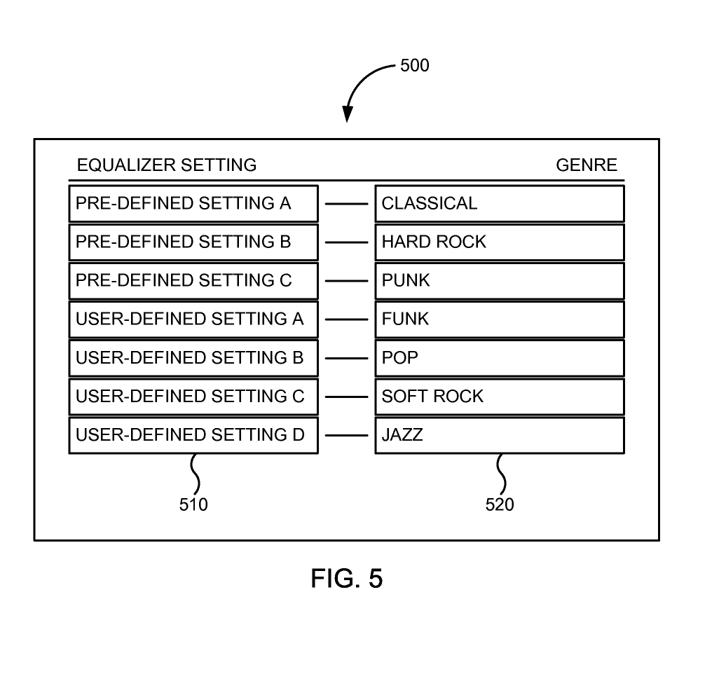

FIGS. 5, 6, and 7 illustrate examples of mappings that may be implemented in various embodiments according to the present invention. Referring to FIG. 5, graphical user interface 500 may include a set of equalizer settings 510 associated with a set of genres 520. In various embodiments, a user may select which pre-defined or user-defined equalizer settings may be associated with or map to a given genre associated with content. In this example, predefined equalizer setting A can be associated with the “classical” genre, predefined equalizer setting B can be associated with the “hard rock” genre, and predefined equalizer settings C can be associated with the “punk” genre. User-defined equalizer setting A can be associated with the “funk” genre, user-defined equalizer setting B can be associated with the “pop” genre, user defined equalizer setting C can be associated with the “soft rock” genre, and user-defined equalizer setting D is associated with the “jazz” genre.

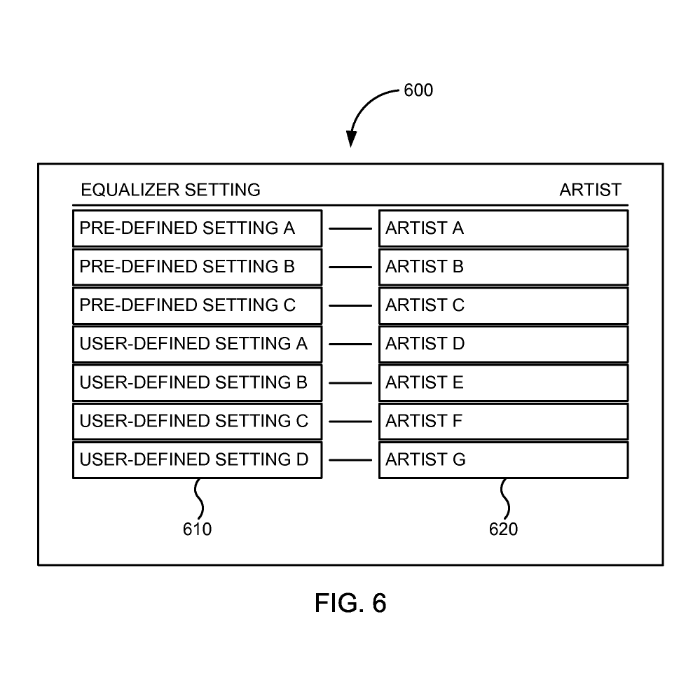

Referring to FIG. 6, graphical user interface 600 may include a set of equalizer settings 610 associated with a set of artist 620. In various embodiments, a user may select which pre-defined or user-defined equalizer settings may be associated with or map to a given artist associated with content. In this example, predefined equalizer setting A can be associated with “Artist A,” predefined equalizer setting B can be associated with “Artist B,” and predefined equalizer settings C can be associated with “Artist C.” User-defined equalizer setting A can be associated with “Artist D,” user-defined equalizer setting B can be associated with “Artist E,” user defined equalizer setting C can be associated with “Artist F,” and user-defined equalizer setting D can be associated with “Artist G.”

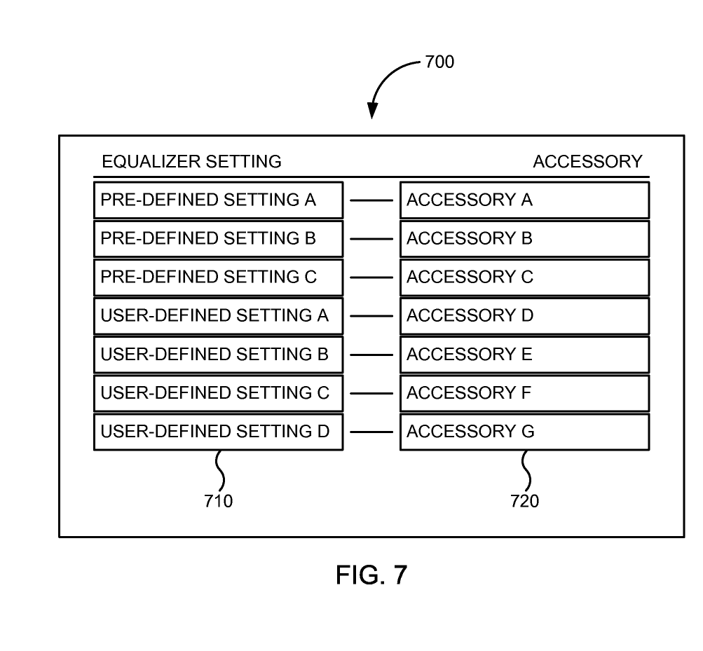

Referring to FIG. 7, graphical user interface 700 may include a set of equalizer settings 710 associated with a set of accessories 720. In various embodiments, a user may select which pre-defined or user-defined equalizer settings may be associated with or map to a given accessory that may be or currently is attached to media player 100. In this example, predefined equalizer setting A can be associated with “Accessory A,” predefined equalizer setting B can be associated with “Accessory B,” and predefined equalizer settings C can be associated with “Accessory C.” User-defined equalizer setting A can be associated with “Accessory D,” user-defined equalizer setting B can be associated with the “Accessory E,” user defined equalizer setting C can be associated with the “Accessory F,” and user-defined equalizer setting D can be associated with the “Accessory G.”

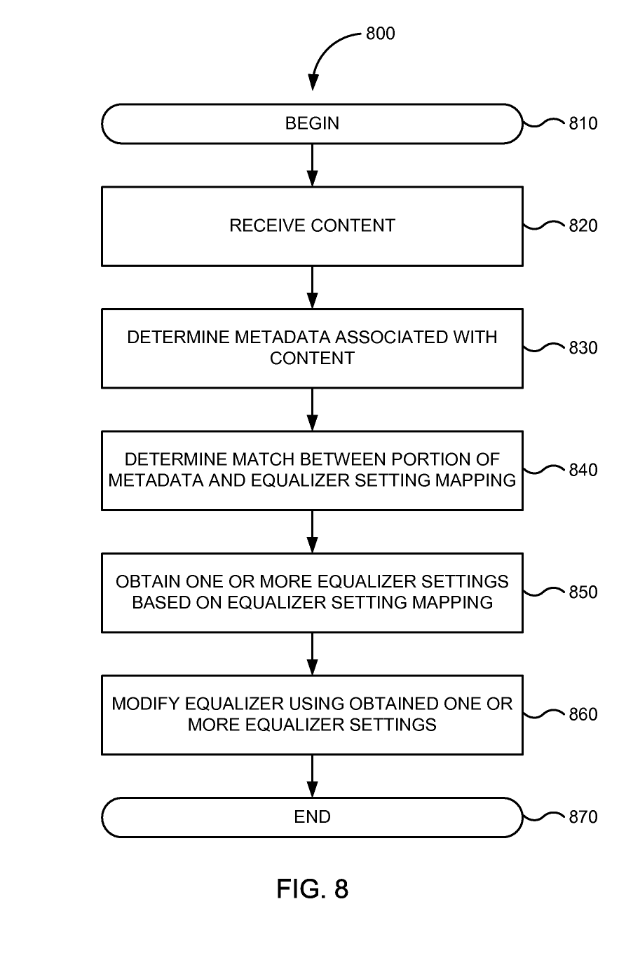

FIG. 8 is a flowchart of method 800 for modifying equalizer settings based on content in one embodiment according to the present invention. FIG. 8 begins in step 810.

In step 820, content is received. In step 830 metadata associated with the content is determined. Some examples of metadata associated with content include MP3 ID tags, title information, artist information, album information, label information, user associated information, bit rate information, encoding information, format information, or the like.

In step 840 a match is determined between a portion of the metadata and an equalizer setting mapping. For example, upon receiving a song, media player 100 may attempt to match a genre associated with the song to one or more equalizer settings using a lookup table. In step 850, one or more equalizer settings are obtained based on the equalizer setting mapping. In step 860, an equalizer is modified or adjusted using the obtained one or more equalizer settings.

Thus, in various embodiments, equalizer setting mappings may be obtained that may enable media player 100 to automatically adjust equalizer settings based on metadata associated with content. FIG. 8 ends in step 870.

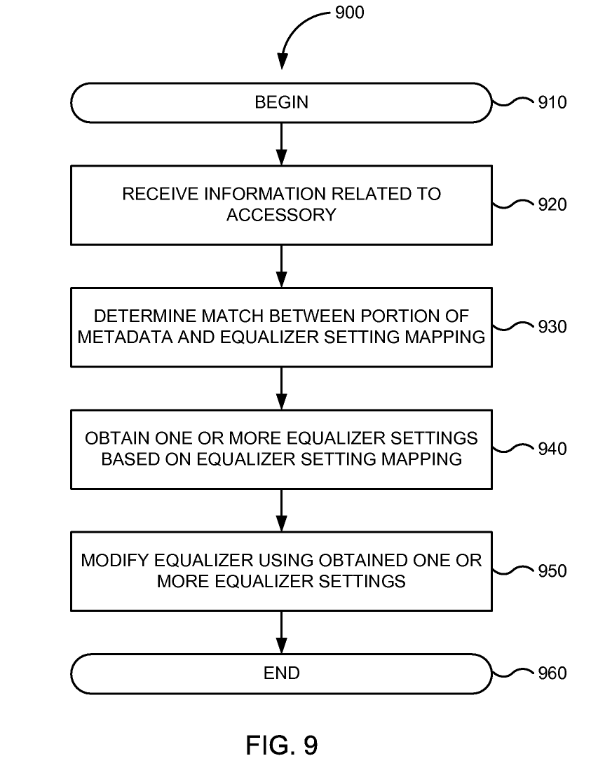

FIG. 9 is a flowchart of method 900 for modifying equalizer settings based on an accessory attached to media player 100 in one embodiment according to the present invention. FIG. 9 begins in step 910.

In step 920, information related to an accessory is received. In various embodiments, media player 100 may generate information indicating that an accessory has been attached. An accessory may communicate with media player 100 when attached directly or indirectly to media player 100. The accessory may provide information identifying the accessory, information identifying a manufacturer associated with the accessory, information indicative of capabilities and functionalities provided by the accessory, information requesting capabilities and functionalities provided by media player 1100 that are to be utilized by the accessory, or the like.

In step 930, a match is determined between a portion of the metadata and an equalizer setting mapping. In step 940, one or more equalizer settings are obtained based on the equalizer setting mapping. In step 950, an equalizer is modified or adjusted using the obtained one or more equalizer settings.

Therefore, in some embodiments, depending on the type or functionality of an accessory, media player 100 may automatically adjust equalizer settings based on the accessory. Media player 100 may modify the equalizer settings based on whether media player 100 is attached to headphones or is attached to a set of speakers. FIG. 9 ends in step 960.

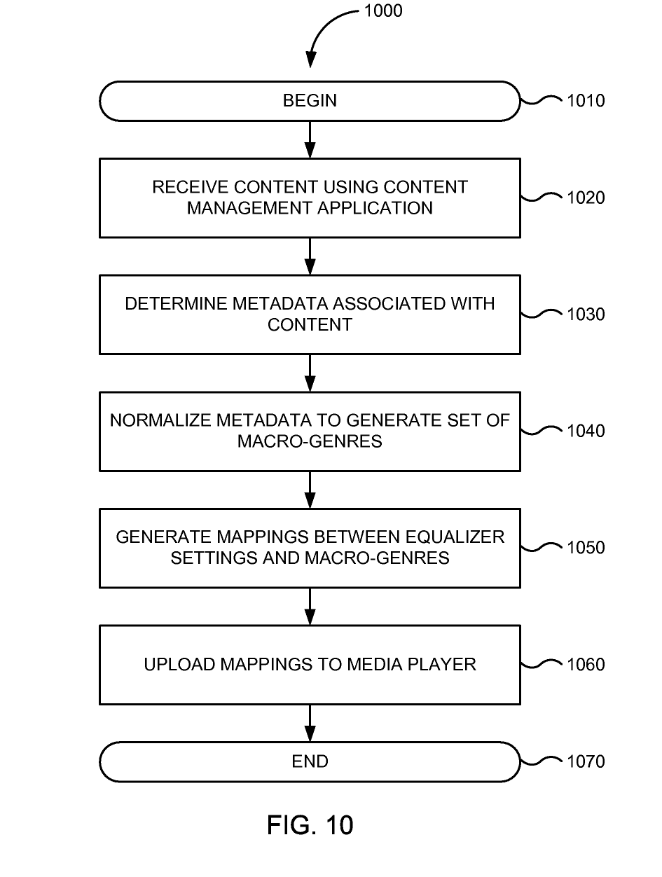

FIG. 10 is a flowchart of method 1000 for uploading equalizer setting mappings to a media player in one embodiment according to the present invention. FIG. 10 begins in step 1000.

In step 1020, content is received using a content management application. The content management application may provide one or more functionalities for storing content or other media assets, organizing content, managing content, indexing content, or the like, and uploading the stored content and associated metadata onto media player 100.

In step 1030, metadata associated with the content is determined. In step 1040, the metadata is normalized to generate a set of macro-genres. One example of a method for generating macro-genres is described further with respect to U.S. patent application Ser. No. ______, filed ______ and entitled “Auto-tagging of Aliases” (Attorney Docket No. 20750P-004210US), the entire disclosure of which is herein incorporated by reference for all purposes. In various embodiments, the metadata may be normalized to generate other sets of information. For example, malformed or otherwise misspelled information may be normalized to be consistent between related content.

In step 1050, mappings are generated between equalizer settings and the macro-genres. In step 1060, the mappings are uploaded to media player 100. For example, in addition to synchronizing content between the content management application and media player 100, the content management application may further upload or otherwise store mappings between equalizer settings and information related to content on media player 100 for subsequent use. FIG. 10 ends in step 1070.

Accordingly, in various embodiments, a media player or portable media device may instructs its own audio hardware to use the automatically-selected EQ settings. In some embodiments, the media player may external audio hardware (e.g., one installed inside an accessory device) to use the EQ setting through one or more signaling mechanisms.

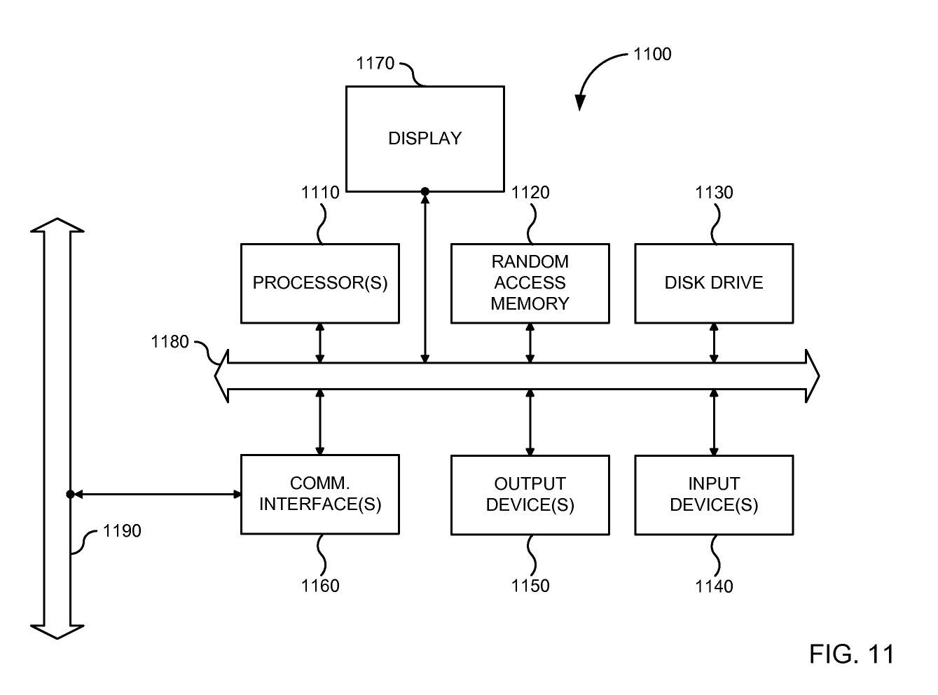

FIG. 11 is a simplified block diagram of a computer system 1100 that may incorporate embodiments of the present invention. FIG. 11 is merely illustrative of an embodiment incorporating the present invention and does not limit the scope of the invention as recited in the claims. One of ordinary skill in the art would recognize other variations, modifications, and alternatives.

In one embodiment, computer system 1100 includes processor(s) 1110, random access memory (RAM) 1120, disk drive 1130, input device(s) 1140, output device(s) 1150, display 1160, communications interface(s) 1170, and a system bus 1180 interconnecting the above components. Other components, such as file systems, storage disks, read only memory (ROM), cache memory, codecs, and the like may be present.

RAM 1120 and disk drive 1130 are examples of tangible media configured to store data such as audio, image, and movie files, operating system code, embodiments of the present invention, including executable computer code, human readable code, or the like. Other types of tangible media include floppy disks, removable hard disks, optical storage media such as CD-ROMS, DVDs and bar codes, semiconductor memories such as flash memories, read-only-memories (ROMS), battery-backed volatile memories, networked storage devices, and the like.

In various embodiments, input device 1140 is typically embodied as a computer mouse, a trackball, a track pad, a joystick, a wireless remote, a drawing tablet, a voice command system, an eye tracking system, a multi-touch interface, a scroll wheel, a click wheel, a touch screen, an FM/TV tuner, audio/video inputs, and the like. Input device 1140 may allow a user to select objects, icons, text, and the like, via a command such as a click of a button or the like. In various embodiments, output device 1150 is typically embodied as a display, a printer, a force-feedback mechanism, an audio output, a video component output, and the like. Display 1160 may include a CRT display, an LCD display, a Plasma display, and the like.

Embodiments of communications interface 1170 may include computer interfaces, such as include an Ethernet card, a modem (telephone, satellite, cable, ISDN), (asynchronous) digital subscriber line (DSL) unit, FireWire interface, USB interface, and the like. For example, these computer interfaces may be coupled to a computer network 1190, to a FireWire bus, or the like. In other embodiments, these computer interfaces may be physically integrated on the motherboard or system board of computer system 1100, and may be a software program, or the like.

In various embodiments, computer system 1100 may also include software that enables communications over a network such as the HTTP, TCP/IP, RTP/RTSP protocols, and the like. In alternative embodiments of the present invention, other communications software and transfer protocols may also be used, for example IPX, UDP or the like.

In various embodiments, computer system 1100 may also include an operating system, such as Microsoft Windows®, Linux®, Mac OS X®, real-time operating systems (RTOSs), open source and proprietary OSs, and the like.

FIG. 11 is representative of a media player and/or computer system capable of embodying the present invention. It will be readily apparent to one of ordinary skill in the art that many other hardware and software configurations are suitable for use with the present invention. For example, the media player may be a desktop, portable, rack-mounted or tablet configuration. Additionally, the media player may be a series of networked computers. Moreover, the media player may be a mobile device, an embedded device, a personal digital assistant, a smart phone, and the like. In still other embodiments, the techniques described above may be implemented upon a chip or an auxiliary processing board.

The present invention can be implemented in the form of control logic in software or hardware or a combination of both. The control logic may be stored in an information storage medium as a plurality of instructions adapted to direct an information-processing device to perform a set of steps disclosed in embodiments of the present invention. Based on the disclosure and teachings provided herein, a person of ordinary skill in the art will appreciate other ways and/or methods to implement the present invention.

The embodiments discussed herein are illustrative of one or more examples of the present invention. As these embodiments of the present invention are described with reference to illustrations, various modifications or adaptations of the methods and/or specific structures described may become apparent to those skilled in the art. All such modifications, adaptations, or variations that rely upon the teachings of the present invention, and through which these teachings have advanced the art, are considered to be within the scope of the present invention. Hence, the present descriptions and drawings should not be considered in a limiting sense, as it is understood that the present invention is in no way limited to only the embodiments illustrated.

The above description is illustrative but not restrictive. Many variations of the invention will become apparent to those skilled in the art upon review of the disclosure. The scope of the invention should, therefore, be determined not with reference to the above description, but instead should be determined with reference to the pending claims along with their full scope or equivalents.

What is claimed is:

1. A method implemented by a media player for playing content, the method comprising:
receiving information related to content;
determining one or more settings for an equalizer associated with the media player based on the information related to the content; and
outputting the content using the one or more determined settings associated with the equalizer.

2. The method of claim 1 wherein determining the one or more settings for the equalizer associated with the media player based on the information related to the content comprises determining a mapping between the information related to the content and the one or more settings.

3. The method of claim 2 further comprising:
receiving from a content management application information indicative of the mapping between the information related to the content and the one or more settings for the equalizer.

4. The method of claim 2 further comprising:
receiving from a user input indicative of the mapping between the portion of the information related to the content and the one or more settings for the equalizer.

5. The method of claim 2 further comprising:
analyzing metadata associated with the content to generate the information related to the content based on matching portions of the metadata to normalized data.

6. The method of claim 1 wherein determining the one or more settings for an equalizer associated with the media player based on the information related to the content comprises determining the one or more settings based on at least one of a title, an artist, an album, a genre, a category, a rating, a bit-rate, an encoding, or a format associated with the content.

7. The method of claim 1 wherein determining the one or more settings for the equalizer associated with the media player based on the information related to the content further comprises determining the one or more settings based on an accessory attached to the media player.

8. A computer readable medium configured to store a set of code modules which when executed by a processor of a media player become operational with the media player for playing content, the computer readable medium comprising:
code for receiving information related to content;
code for determining one or more settings for an equalizer associated with the media player based on the information related to the content; and
code for outputting the content using the one or more determined settings associated with the equalizer.

9. The computer readable medium of claim 8 wherein the code for determining the one or more settings for the equalizer associated with the media player based on the information related to the content comprises code for determining a mapping between the information related to the content and the one or more settings.

10. The computer readable medium of claim 9 further comprising:
code for receiving from a content management application information indicative of the mapping between the information related to the content and the one or more settings for the equalizer.

11. The computer readable medium of claim 9 further comprising:
code for receiving from a user input indicative of the mapping between the portion of the information related to the content and the one or more settings for the equalizer.

12. The computer readable medium of claim 9 further comprising:
code for analyzing metadata associated with the content to generate the information related to the content based on matching portions of the metadata to normalized data.

13. The computer readable medium of claim 8 wherein the code for determining the one or more settings for an equalizer associated with the media player based on the information related to the content comprises determining the one or more settings based on at least one of a title, an artist, an album, a genre, a category, a rating, a bit-rate, an encoding, or a format associated with the content.

14. The computer readable medium of claim 8 wherein the code for determining the one or more settings for the equalizer associated with the media player based on the information related to the content further comprises code for determining the one or more settings based on an accessory attached to the media player.

15. A system for playing content, the system comprising:
a processor; and
a memory coupled to the processor, the memory configured to store a set of instructions which when executed by the processor become operational with the processor to:
receive information related to content;
determine one or more settings for an equalizer based on the information related to the content; and
output the content using the one or more determined settings associated with the equalizer.

16. The system of claim 15 wherein the set of instructions become operational with the processor to determine the one or more settings for the equalizer based on a mapping between the information related to the content and the one or more settings.

17. The system of claim 16 wherein the set of instructions become operational with the processor to:
receive from a content management application information indicative of the mapping between the information related to the content and the one or more settings for the equalizer.

18. The system of claim 16 wherein the set of instructions become operational with the processor to:
receive from a user input indicative of the mapping between the portion of the information related to the content and the one or more settings for the equalizer.

19. The system of claim 16 wherein the set of instructions become operational with the processor to:
analyze metadata associated with the content to generate the information related to the content based on matching portions of the metadata to normalized data.

20. The system of claim 15 wherein the set of instructions become operational with the processor to determine the one or more settings for the equalizer based on at least one of a title, an artist, an album, a genre, a category, a rating, a bit-rate, an encoding, or a format associated with the content.

21. The system of claim 15 wherein the set of instructions become operational with the processor to determining the one or more settings for the equalizer based on the presence of an accessory.
